(19) United States
(12) Patent Application Publication
(10) Pub. No.: US 2022/0170152 A1
(43) Pub. Date: Jun. 2, 2022

(54) ELECTROCHEMICAL DEPOSITION APPARATUS SET AND ELECTROCHEMICAL DEPOSITION METHOD

(71) Applicant: BOE TECHNOLOGY GROUP CO., LTD., Beijing (CN)

(72) Inventors: Guangcai YUAN, Beijing (CN); Junwei YAN, Beijing (CN); Chengfei WANG, Beijing (CN); Guocai ZHANG, Beijing (CN); Shihao DONG, Beijing (CN); Shaodong SUN, Beijing (CN); Qi QI, Beijing (CN); Zhanfeng CAO, Beijing (CN)

(21) Appl. No.: 17/488,234

(22) Filed: Sep. 28, 2021

(30) Foreign Application Priority Data
Nov. 27, 2020 (CN) 202011367346.7

(51) Int. Cl. C23C 16/44; C23C 16/458

(52) U.S. Cl. CPC C23C 16/4414; C23C 16/4412; C23C 16/4583

(57) ABSTRACT

The present disclosure provides an electrochemical deposition apparatus set. The electrochemical deposition apparatus set includes: an electrochemical deposition device configured to form an electrochemical deposition film layer on an area to be coated of a substrate; an antioxidation treatment device located on a side of the electrochemical deposition device and configured to performing antioxidation treatment on the substrate formed with the electrochemical deposition film layer; a transmission device configured to carry the substrate and drive the substrate to move at least from the electrochemical deposition device to the antioxidation treatment device.

### CROSS-REFERENCE TO RELATED APPLICATION

This disclosure claims priority from the Chinese Patent Application No. 202011367346.7 filed on Nov. 27, 2020, the entire disclosure of which is hereby incorporated by reference.

### TECHNICAL FIELD

The present disclosure relates to the field of electrochemical deposition, and particularly relates to an electrochemical deposition apparatus set and an electrochemical deposition method.

### BACKGROUND

The electrochemical deposition process is a low-cost chemical film forming mode that can obtain a metal layer of any thickness by deposition.

### SUMMARY

According to one aspect of the present disclosure, there is provided an electrochemical deposition apparatus set. The electrochemical deposition apparatus set includes:

an electrochemical deposition device configured to form an electrochemical deposition film layer on an area to be coated of a substrate;

an antioxidation treatment device located on a side of the electrochemical deposition device and configured to performing antioxidation treatment on the substrate formed with the electrochemical deposition film layer; and

a transmission device configured to carry the substrate and drive the substrate to move at least from the electrochemical deposition device to the antioxidation treatment device.

In some embodiments, the antioxidation treatment device includes:

an antioxidation tank;

a first liquid collection tank having a first liquid inlet in communication with a supply device supplying an antioxidant solution, and a second liquid inlet in communication with a liquid outlet of the antioxidation tank;

a first filtering mechanism having a liquid inlet in communication with the liquid outlet of the first liquid collection tank, wherein the first filtering mechanism is configured to filter the received antioxidant solution; and

a plurality of first sprayers arranged in the antioxidation tank, the first sprayers being in communication with the liquid outlet of the first filtering mechanism, and configured to spray the filtered antioxidant solution toward the substrate formed with the electrochemical deposition film layer;

wherein the antioxidant solution chemically reacts with the electrochemical deposition film layer to form a protective layer on a surface of the electrochemical deposition film layer.

In some embodiments, the electrochemical deposition apparatus set further includes a pickling device configured to spray a pickling solution toward the area to be coated of the substrate; and

wherein the transmission device is further configured to drive the substrate to move from the pickling device to the electrochemical deposition device.

In some embodiments, the pickling device includes:

a pickling tank;

a second liquid collection tank having a first liquid inlet in communication with a supply device supplying a pickling solution, and a second liquid inlet in communication with a liquid outlet of the pickling device;

a second filtering mechanism having a liquid inlet in communication with the liquid outlet of the second liquid collection tank, and configured to filter the received pickling solution; and

a plurality of second sprayers arranged in the pickling tank, the second sprayers being in communication with the liquid outlet of the second filtering mechanism, and configured to spray the filtered pickling solution toward the substrate.

In some embodiments, the electrochemical deposition apparatus set further includes: a first cleaning device located on a side of the antioxidation treatment device close to the electrochemical deposition device and configured to spray a first cleaning liquid toward the substrate formed with the electrochemical deposition film layer; and

the transmission device is configured to drive the substrate to move from the electrochemical deposition device to the first cleaning device, and from the first cleaning device to the antioxidation treatment device.

In some embodiments, the electrochemical deposition apparatus set further includes: a second cleaning device and a drying device;

wherein the second cleaning device is located on a side of the antioxidation treatment device away from the first cleaning device, and is configured to spray a second cleaning liquid toward the substrate that has been subjected to the antioxidation treatment.

The drying device is configured to dry the substrate that has been cleaned by the second cleaning liquid; and

wherein the transmission device is further configured to drive the substrate to move from the antioxidation treatment device to the second cleaning device and the drying device in sequence.

In some embodiments, the electrochemical deposition device and the antioxidation treatment device are arranged along a first direction; the transmission apparatus including: guide rails, a bracket, a grasping mechanism, and a driving mechanism; wherein the guide rails are arranged on opposite sides of the electrochemical deposition device and extend along the first direction; the bracket is slidably arranged on the guide rails; the grasping mechanism is arranged on the bracket and configured to pick and place the substrate; and the driving mechanism is connected to the bracket and configured to drive the bracket to move along the guide rails so as to drive the substrate to move at least from the electrochemical deposition device to the antioxidation treatment device.

In some embodiments, the transmission device further includes a carrier configured to carry the substrate; and the grasping mechanism is configured to pick and place the carrier to realize the pick and place of the substrate.

In some embodiments, the bracket includes: a first upright portion, a second upright portion, and a lifting beam connected between the first upright portion and the second upright portion;

wherein the first upright portion and the second upright portion are respectively arranged on the guide rails on opposite sides of the electrochemical deposition device, and the grasping mechanism is arranged on the lifting beam.

In some embodiments, the electrochemical deposition apparatus set further includes: a feeding device and a loading device;

wherein the feeding device is configured to receive the substrate to be electrochemically deposited, turn the received substrate from a horizontal state to an upright state, and deliver the substrate to the loading device; and

wherein the loading device is located between the feeding device and the electrochemical deposition device, and configured to fix the substrate in the upright state onto the carrier.

In some embodiments, the electrochemical deposition apparatus set further includes: a storage rack located on a side of the electrochemical deposition device away from the antioxidation treatment device, and configured to store the carrier.

According to another aspect of the present disclosure, there is provided an electrochemical deposition method. The electrochemical deposition method includes:

performing electrochemical deposition on a substrate to be electrochemically deposited, so as to form an electrochemical deposition film layer on an area to be coated of the substrate; and

performing antioxidation treatment on the substrate formed with the electrochemical deposition film layer.

In some embodiments, the step of performing electrochemical deposition on the substrate to be electrochemically deposited, and the step of performing antioxidation treatment on the substrate formed with the electrochemical deposition film layer are implemented when the substrate is in an upright state.

According to yet another aspect of the present disclosure, there is provided an electrochemical deposition method, the method including:

spraying a pickling solution toward a substrate to be electrochemically deposited;

performing electrochemical deposition on the substrate sprayed with the pickling solution, so as to form an electrochemical deposition film layer on an area to be coated of the substrate;

cleaning the substrate formed with the electrochemical deposition film layer for a first time;

performing antioxidation treatment on the substrate after the first cleaning; and

cleaning the substrate subjected to the antioxidation treatment for a second time, and drying the substrate after the second cleaning.

In some embodiments, before spraying the pickling solution toward the substrate to be electrochemically deposited, the method further includes: receiving the substrate in a horizontal state, and turning the substrate into an upright state; and

wherein after drying the substrate after the second cleaning, the method further includes: turning the substrate from the upright state back to the horizontal state.

### BRIEF DESCRIPTION OF THE DRAWINGS

Accompanying drawings are provided for further understanding of the present disclosure and constitute a part of the specification. Hereinafter, these drawings are intended to explain the present disclosure together with the following specific embodiments, but is not to be construed as limiting the present disclosure. In the drawings:

FIG. 1A is an overall top view of an electrochemical deposition apparatus set provided in some embodiments of the present disclosure.

FIG. 1B is a perspective view of an electrochemical deposition apparatus set provided in some embodiments of the present disclosure.

FIG. 2 is a schematic diagram of a transmission device provided in some embodiments of the present disclosure.

FIG. 3 is a schematic diagram of an electrochemical deposition device provided in some embodiments of the present disclosure.

FIG. 4A is an overall schematic diagram of an antioxidation treatment device provided in some embodiments of the present disclosure.

FIG. 4B is a schematic diagram showing a positional relationship among an antioxidation tank, a first liquid collection tank, and a first sprayers within an antioxidation treatment device provided in some embodiments of the present disclosure.

FIG. 5A is a schematic diagram of a pickling device provided in some embodiments of the present disclosure.

FIG. 5B is a schematic diagram showing a positional relationship among a pickling tank, a second liquid collection tank, and second sprayers within a pickling device provided in some embodiments of the present disclosure.

FIG. 6A is a schematic diagram of a first cleaning device provided in some embodiments of the present disclosure.

FIG. 6B is a schematic diagram showing a positional relationship among a cleaning tank, a third liquid collection tank, and third sprayers within a first cleaning device provided in some embodiments of the present disclosure.

FIG. 7 is a schematic diagram of a storage rack provided in some embodiments of the present disclosure.

FIG. 8 is a schematic diagram of a second supply device provided in some embodiments of the present disclosure.

FIG. 9 is a flowchart of an electrochemical deposition method provided in some embodiments of the present disclosure.

FIG. 10 is a flowchart of an electrochemical deposition method according to further embodiments of the present disclosure.

### DETAILED DESCRIPTION

To make the objects, technical solutions and advantages of the present disclosure clearer, the technical solutions of the embodiments of the present disclosure will be described clearly and completely below with reference to the accompanying drawings of the embodiments of the present disclosure. It is apparent that the embodiments described herein are some of the embodiments of the present disclosure, but not all of the embodiments. All other embodiments, which are obtained by those skilled in the art based on the described embodiments of the present disclosure without inventive work, are within the protection scope of the present disclosure. Furthermore, different embodiments and features thereof in the present disclosure can be combined with each other if no conflict is caused.

The terms used herein for describing embodiments of the present disclosure are not intended to limit and/or define the scope of the present disclosure. For example, unless otherwise defined, technical or scientific terms used in the present disclosure have general meanings as understood by those of ordinary skill in the art. It should be understood that the words “first”, “second” and the like used in the present disclosure do not indicate any order, quantity, or importance, but are used merely for distinguishing different components. The singular forms “a,” “an,” or “the” and similar referents do not denote a limitation of quantity, but rather denote the presence of at least one, unless the context clearly dictates otherwise. The word “include” or “comprise”, and the like, is intended to mean that the element or item preceding the word contains the element or item listed after the word and its equivalent, but does not exclude other elements or items. Words “upper”, “lower”, “left”, “right” and the like are merely used to indicate a relative positional relationship, and when an absolute position of the described object is changed, the relative positional relationship may also be changed accordingly.

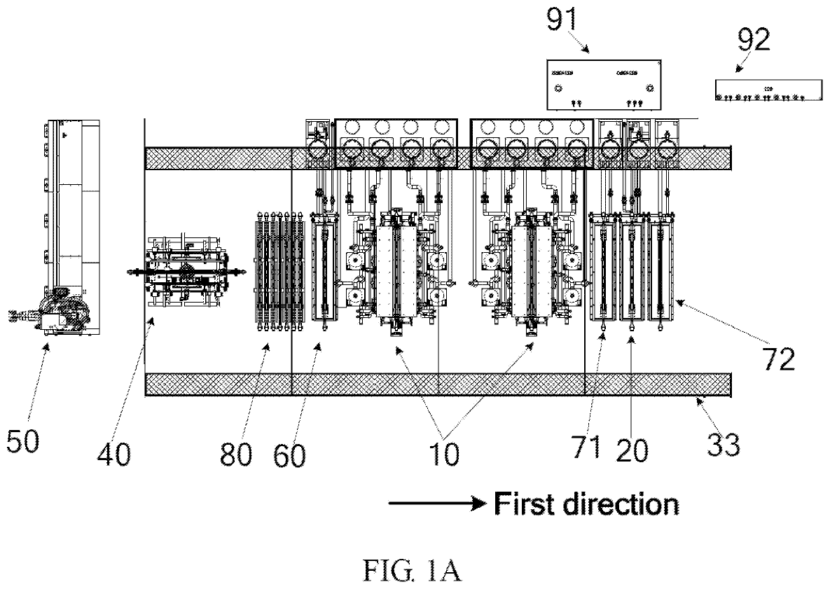

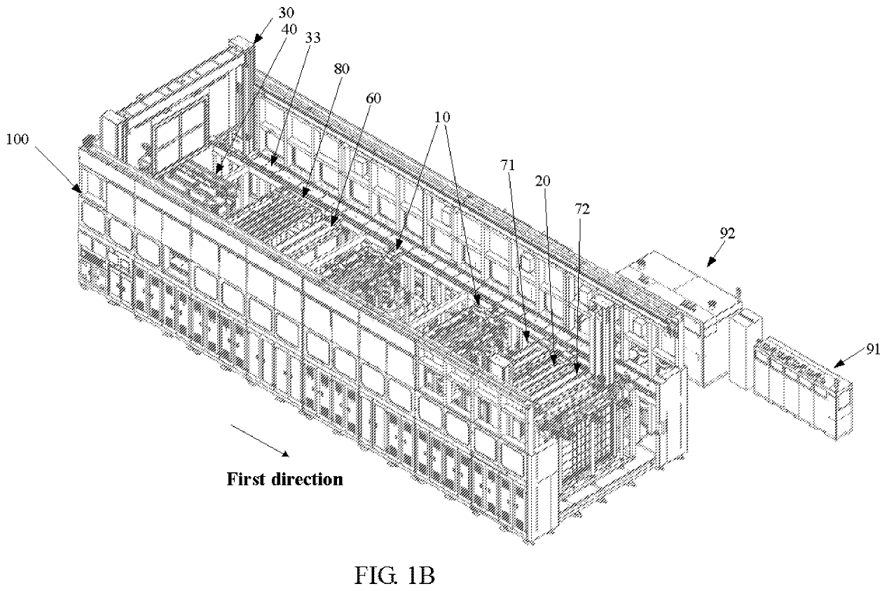

FIG. 1A is an overall top view of an electrochemical deposition apparatus set provided in some embodiments of the present disclosure. FIG. 1B is a perspective view of an electrochemical deposition apparatus set provided in some embodiments of the present disclosure. As shown in FIG. 1A or 1B, the electrochemical deposition apparatus set according an embodiment of the present disclosure includes: an electrochemical deposition device 10, an antioxidation treatment device 20 and a transmission device 30.

The electrochemical deposition device 10 is configured to perform electrochemical deposition on a substrate to form an electrochemical deposition film layer on an area to be coated of the substrate. It will be appreciated that the electrochemical deposition refers to a technique of obtaining a metal coating on the substrate through migration of positive and negative ions in an electrolyte solution containing metal ions under the action of an external electric field, and through the reduction of metal ions at the cathode. For example, when the metal ions in the electrolyte solution are copper ions, the obtained metal coating is a copper film layer. The substrate may be a panel for a display device, for example, but not limited to, a glass substrate for a Mini/Micro-LED display device. A metal film of 2-20 um thick is deposited on the glass substrate, which can reduce the resistance value and heat emission, and greatly improve the service life. Compared with other methods of metal deposition such as sputtering and chemical plating, depositing metal film on the substrate in an electrochemical manner has the advantages of high efficiency, low stress, low risk of foreign matter inclusion and the like.

The antioxidation treatment device 20 is located on a side of the electrochemical deposition device 10 and configured to perform antioxidation treatment on the substrate formed with the electrochemical deposition film layer. The antioxidation treatment may refer to spraying an antioxidant solution toward (and onto) the electrochemical deposition film layer on the substrate so that a part of the electrochemical deposition film layer reacts with the antioxidant solution to form a protective layer on a surface of the electrochemical deposition film layer. In the embodiment shown in FIG. 1A or 1B, the antioxidation treatment device 20 is located on a side of the electrochemical deposition device 10 in a first direction, and a first cleaning device 71 (further described below) is provided between the antioxidation treatment device 20 and the electrochemical deposition device 10. In other embodiments, the antioxidation treatment device 20 and the electrochemical deposition device 10 may be arranged next to each other.

The transmission device 30 is configured to carry the substrate and drive the substrate to move at least from the electrochemical deposition device to the antioxidation treatment device, such that the substrate is subjected to the antioxidation treatment after the electrochemical deposition process.

In some embodiments, the electrochemical deposition apparatus set further includes a first supply device 91 and a second supply device 92. The first supply device 91 is configured to supply an electrolyte solution for electrochemical deposition to the electrochemical deposition device 10; and the second supply device 92 is configured to supply an antioxidant solution to at least the antioxidation treatment device 20.

The inventor has found that, in the process of the electrochemical deposition, the electrochemical deposition film layer (e.g., a copper layer) is quickly oxidized after being formed on the substrate, which leads to deteriorated electrical performance (e.g., increased resistance) of the electrochemical deposition film layer. In this case, when the substrate formed with the electrochemical deposition film layer is used in a display device, the signal transmission effect, and thus the display effect, of the display device is affected. In contrast, in the embodiments of the present disclosure, after the electrochemical deposition film layer is formed on the substrate with the electrochemical deposition device 10, the transmission device 30 moves the substrate from the electrochemical deposition device 10 to the antioxidation treatment device so that the antioxidation treatment device 20 performs antioxidation treatment on the electrochemical deposition film layer on the substrate to form a protective layer on the surface of the electrochemical deposition film layer, thereby preventing the electrochemical deposition film layer from being oxidized, and ensuring the electrical performance of the electrochemical deposition film layer.

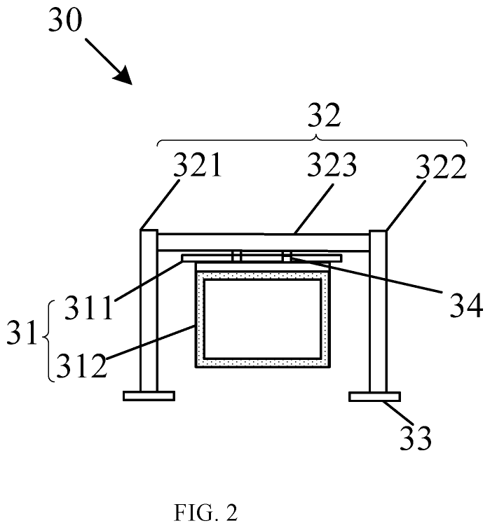

FIG. 2 is a schematic diagram of a transmission device provided in some embodiments of the present disclosure. As shown in FIG. 2, the transmission device 30 includes: a carrier 31, a bracket 32, a grasping mechanism 34, a driving mechanism (not shown), and guide rails 33 arranged on opposite sides of the electrochemical deposition device 10. The guide rails 33 extend along a first direction, which is the arrangement direction of the electrochemical deposition device 10 and the antioxidation treatment device. As shown in FIG. 1B, the guide rails 33 are provided on a mounting rack 100. Here, each of the opposite sides of the electrochemical deposition device 10 is different from the above-mentioned “a side” of the electrochemical deposition device. In some embodiments, as shown in FIGS. 1A and 1B, the guide rails 33 are also positioned on opposite sides of a pickling device 60, a first cleaning device 71, a second cleaning device 72, and/or a storage rack 80.

The carrier 31 is configured to carry the substrate. When the substrate carried on the carrier 31 is subjected to the electrochemical deposition process, the carrier 31 is connected to a negative output of the power supply, while an anode structure of the electrochemical deposition device 10 is connected to a positive output of the power supply, so that an electric field is formed between the anode structure and the substrate, and therefore, metal ions (for example, Cu ions, Ni ions, Ag ions, or the like) in the electrolyte solution for electrochemical deposition are attached to the substrate to form an electrochemical deposition film layer. In some implementations, as shown in FIG. 2, the substrate may be attached to the carrier 31. The carrier 31 may fix the substrate by suction, grabbing, locking, etc. In some implementations, the carrier 31 may carry one, two, or more substrates at the same time.

The bracket 32 is slidably arranged on the guide rails 33, and the driving mechanism 34 is connected to the bracket 32 and configured to drive the bracket 32 to move along the guide rails 33. For example, the bracket 32 may include: a first upright portion 321, a second upright portion 322, and a lifting beam 323 connected between the first upright portion 321 and the second upright portion 322. Two ends of the lifting beam 323 are slidably arranged on the first upright portion 321 and the second upright portion 322, respectively, so that the lifting beam 323 may move up and down.

The grasping mechanism 34 is arranged on the bracket 32 and configured to pick and place the carrier 31. The grasping mechanism 34 may be arranged on the lifting beam 323. For example, the grasping mechanism 34 may include a hook for hooking up the carrier 31. Alternatively, the grasping mechanism 34 may include a gripper for gripping the carrier 31. Through up and down of the lifting beam 323, the grasping mechanism 34, and thus the carrier 31, are driven to move up and down. For example, during the electrochemical deposition, the lifting beam 323 first drives the carrier 31 to move downward so that the carrier 31 is placed in a region of the electrochemical deposition device 10 where the electrochemical deposition process is to be performed (immersed in the electrolyte solution). Then, the lifting beam 323 drives the carrier 31 to move upward, and then move along the guide rails 33. When the lifting beam 323 has moved to the above of the antioxidation treatment device 20, the lifting beam 323 moves downward to place the substrate on the carrier 31 in a region of the antioxidation treatment device 20 where the antioxidation process is to be performed.

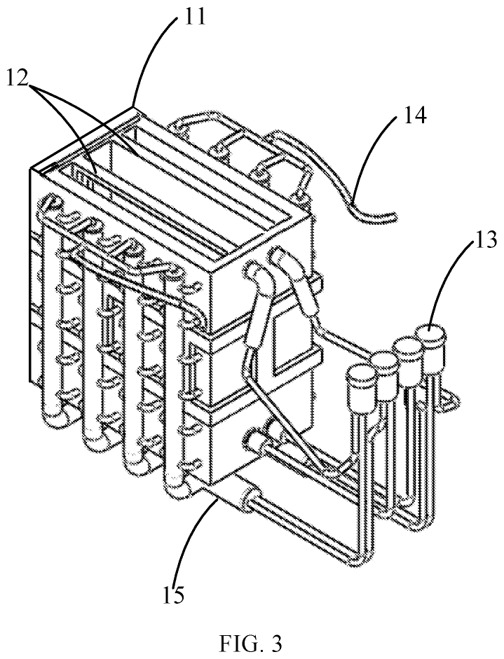

FIG. 3 is a schematic diagram of an electrochemical deposition device provided in some embodiments of the present disclosure. As shown in FIG. 3, the electrochemical deposition device 10 includes: an anode structure 12 and a receiving tank 11. During the electrochemical deposition, the receiving tank 11 contains an electrolyte solution; the anode structure 12 and the carrier 31 carrying the substrate are both disposed in the receiving tank 11; a seed layer is formed on a surface of the substrate; and the anode structure 12 and the carrier 31 are disposed opposite to each other. The carrier 31 is connected to a negative output of the power supply and electrically connects the negative output of the power supply to the seed layer on the substrate. The anode structure 12 is connected to a positive output of a power supply so as to form an electric field between the anode structure 12 and the substrate, and in turn cause metal ions (for example, Cu ions, Ni ions, Ag ions, or the like) in the electrolyte solution to be attached to the substrate to form the electrochemical deposition film layer.

In some embodiments, the carrier 31 may be used to carry two substrates simultaneously, and accordingly, there are two anode structures 12 (see FIG. 3). The two anode structures 12 are disposed opposite to each other and located on opposite sides of the substrate carried on the carrier 31, respectively, so as to perform electrochemical deposition on the two substrates simultaneously, which improves the productivity and saves the electrolyte solution.

The electrochemical deposition device 10 may further include: an exhaust pipeline 14, a drain pipeline 15, and a fourth filtering mechanism 13. An inlet of the drain pipeline 15 is in communication with the receiving tank 11. The fourth filtering mechanism 13 has a filter inlet and a filter outlet. The filter inlet is in communication with an outlet of the drain pipeline 15, the filter outlet is in communication with a liquid inlet of the receiving tank 11, and the fourth filtering mechanism 13 is configured to filter the electrolyte solution flowing into the filter inlet thereof to filter out some impurities in the electrolyte solution. The exhaust pipeline 14 is in communication with the top of the drain pipeline 15 to exhaust gases in the electrolyte solution.

In the electrochemical deposition device 10, at least a part of the electrolyte solution in the receiving tank 11 flows from the liquid outlet into the fourth filtering mechanism 13 which then filters out impurities in the electrolyte solution and supplies the filtered electrolyte solution to the receiving tank 11. As a result, circulation is realized and the production cost is saved. After a certain number of substrates have been electrochemical deposited, a concentration of the electrolyte solution output from the fourth filtering mechanism 13 is lower than a predetermined value. Then, the first supply device 91 may supply extra electrolyte solution to replenish the receiving tank 11.

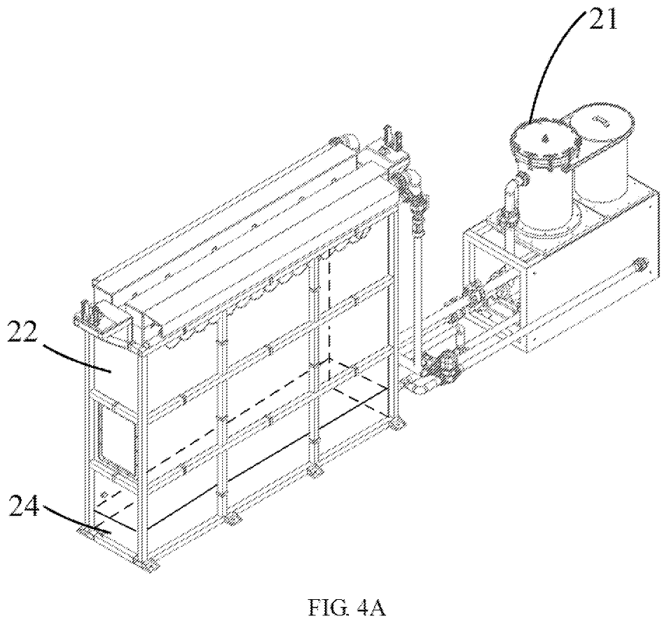

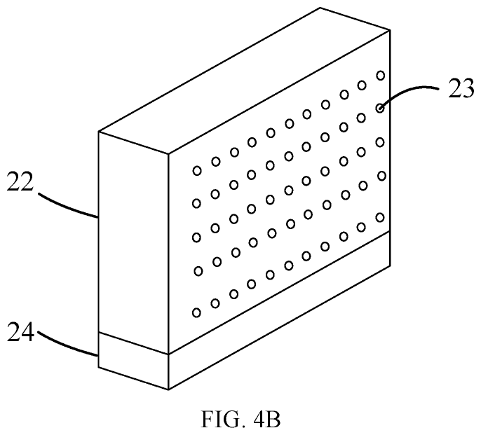

FIG. 4A is an overall schematic diagram of an antioxidation treatment device provided in some embodiments of the present disclosure. FIG. 4B is a schematic diagram showing a positional relationship among the antioxidation tank, the first liquid collection tank, and the first sprayers within the antioxidation treatment device provided in some embodiments of the present disclosure. As shown in FIGS. 4A and 4B, the antioxidation treatment device 20 includes a first filtering mechanism 21, an antioxidation tank 22, a first liquid collection tank 24, and further includes a plurality of first sprayers 23 arranged in the antioxidation tank 22. For example, the first sprayers 23 are distributed in an array on an inner wall of the antioxidation tank 22.

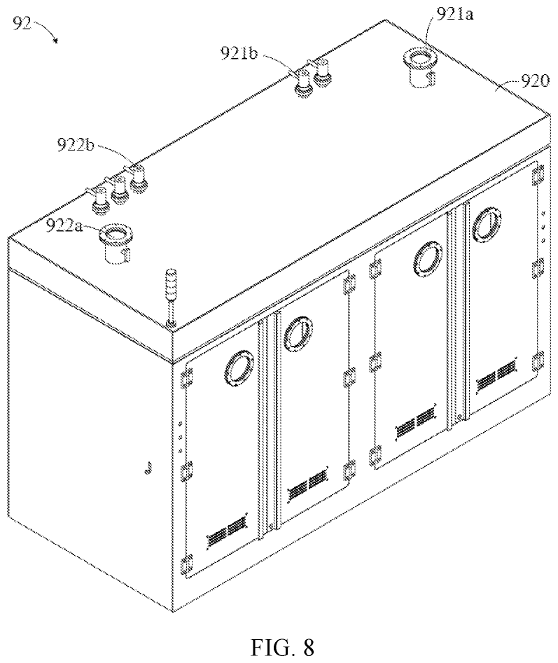

The first liquid collection tank 24 is located below the antioxidation tank 22, and the first liquid collection tank 24 and the antioxidation tank 22 may form an integral structure. The first liquid collection tank 24 has a first liquid inlet in communication with the second supply device 92 (see FIG. 8) to receive the antioxidant solution supplied by the second supply device 92; and a second liquid inlet in communication with a liquid outlet 24 of the antioxidation tank 22. A liquid outlet of the first liquid collection tank 24 is in communication with a liquid inlet of the first filtering mechanism 21, and a liquid outlet of the first filtering mechanism 21 is in communication with liquid inlets of the first sprayers 23. The first filtering mechanism 21 is configured to filter the received antioxidant solution to filter out impurities in the antioxidant solution. The antioxidant solution chemically reacts with the electrochemical deposition film layer on the substrate to form a protective layer on the surface of the electrochemical deposition film layer.

In the antioxidation treatment device 20, after reacting with the electrochemical deposition film layer on the substrate, the antioxidant solution sprayed from the first sprayers 23 onto the substrate flows from the liquid outlet of the antioxidation tank 22 into the first liquid collection tank 24, and then enters the first filtering mechanism 21 through the first liquid collection tank 24, where the first filtering mechanism 21 filters out impurities in the solution and supplies the filtered solution to the first sprayers 23. As a result, circulation is realized and the production cost is saved. After a certain number of substrates have been electrochemical deposited, a concentration of the antioxidant solution output from the first filtering mechanism 21 is lower than a predetermined value, the second supply device 92 may supply extra antioxidant solution to replenish the first liquid inlet of the first liquid collection tank 24.

In some embodiments, as shown in FIGS. 1A and 1B, the electrochemical deposition apparatus set further includes: a feeding device 50 and a loading device 40.

The feeding device 50 is configured to receive the substrate to be electrochemically deposited transferred from an upstream device. The substrate received by the feeding device 50 is in a horizontal state (i.e., a plate surface of the substrate is substantially parallel to the horizontal plane), and the feeding device 50 is further configured to turn the substrate from the horizontal state to an upright state, and deliver the substrate to the loading device 40. The feeding device 50 may include: a manipulator and a manipulator driving mechanism. The manipulator is configured to fix the substrate. For example, the manipulator is provided with a suction disc for fixing the substrate by suction. The manipulator driving mechanism is configured to drive the manipulator to roll and move so as to turn the substrate from the horizontal state to the upright state and deliver the substrate to the loading device 40. The loading device 40 is configured to fix the substrate in the upright state to the carrier 31.

Further, the loading device 40 may be configured to unload the substrate from the carrier 31 and transfer the unloaded substrate to the feeding device 50, which may turn the substrate from the upright state back to the horizontal state, and transfer the substrate to a downstream device.

In some embodiments, two feeding devices and two loading devices may be provided. Among them, an upstream feeding device is configured to turn the substrate from the horizontal state to the upright state, and deliver the substrate to an upstream loading device; a downstream loading device is configured to unload the substrate, which has experienced electrochemical deposition, antioxidation treatment and optional pickling and cleaning treatment, from the carrier, and transfer the unloaded substrate to a downstream feeding device; the downstream feeding device then turns the substrate from the upright state back to the horizontal state, and transfers the substrate to a device downstream of the electrochemical deposition apparatus set.

In some embodiments, as shown in FIGS. 1A and 1B, the electrochemical deposition apparatus set further includes a pickling device 60. The pickling device 60 is located between the loading device 40 and the electrochemical deposition device 10. The pickling device 60 is configured to spray a pickling solution toward the area to be coated of the substrate to pickling the substrate. In this case, the transmission device 30 is further configured to, before driving the substrate to move from the electrochemical deposition device 10 to the antioxidation treatment device 20, drive the substrate to move to the pickling device 60 for pickling, and then to the electrochemical deposition device 10. Driving the substrate to move to the pickling device 60 means driving the substrate to move to a region of the pickling device 60 where the pickling process is to be performed. Before reaching the pickling device 60, the substrate is deposited with a seed layer on the surface. By spraying a pickling solution toward the substrate, surface adhesion of the seed layer can be changed so that in the subsequent electrochemical deposition, the electrochemical deposition film layer formed on the substrate has better adhesion. Exemplarily, the pickling solution is sulfuric acid.

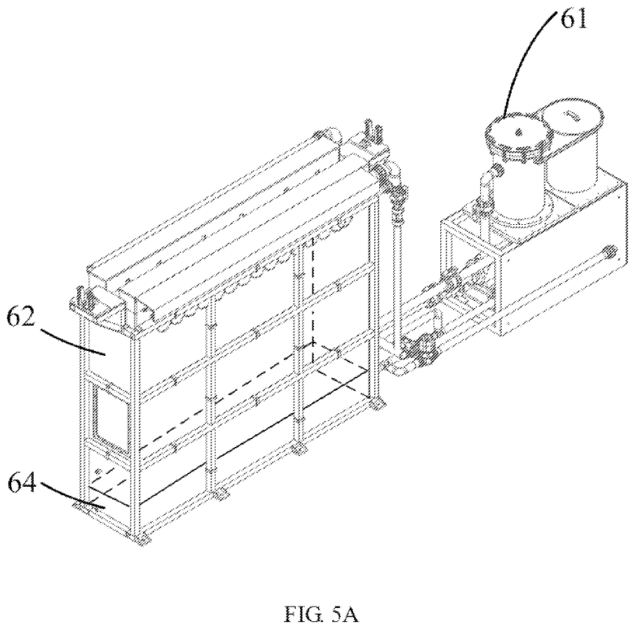

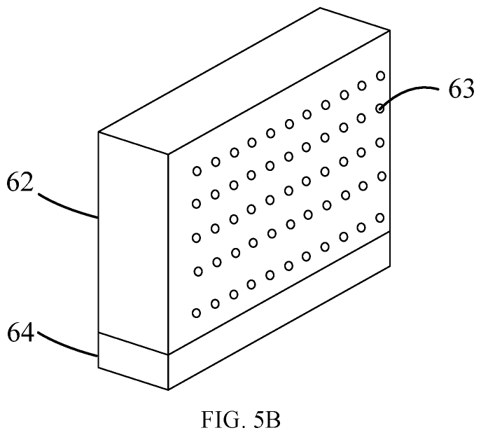

FIG. 5A is a schematic diagram of a pickling device provided in some embodiments of the present disclosure. FIG. 5B is a schematic diagram showing a positional relationship among a pickling tank, a second liquid collection tank, and second sprayers within a pickling device provided in some embodiments of the present disclosure. As shown in FIGS. 5A and 5B, the pickling device 60 includes: a second filtering mechanism 61, a pickling tank 62, and a second liquid collection tank 64, and further includes a plurality of second sprayers 63 disposed in the pickling tank 62. The above-mentioned region where the pickling process is to be performed is located in the pickling tank 62.

The second liquid collection tank 64 is located below the pickling tank 62, and the second liquid collection tank 64 and the pickling tank 62 may form an integral structure. The second liquid collection tank 64 has: a first liquid inlet which is in communication with the second supply device 92 to receive the pickling solution supplied by the second supply device 92; and a second liquid inlet in communication with a liquid outlet of the pickling tank 62. A liquid outlet of the second liquid collection tank 64 is in communication with a liquid inlet of the second filtering mechanism 61, and a liquid outlet of the second filtering mechanism 61 is in communication with liquid inlets of the second sprayers 63. The second filtering mechanism 61 is configured to filter the pickling solution having entered the liquid inlet thereof to filter out impurities in the pickling solution. A plurality of second sprayers 63 are arranged in the pickling tank 62, with liquid outlets of the second sprayers 63 facing the region where the pickling process is to be performed. For example, the liquid outlet of each of the plurality of second sprayers 63 is in communication with the liquid outlet of the second filtering mechanism 61 via a transmission pipeline. For example, the second sprayers 63 are arranged in an array on an inner wall of the pickling tank 62, so that the pickling solution is uniformly sprayed on the substrate in the pickling tank 62.

In the pickling device 60, after reacting with the seed layer on the substrate, the pickling solution sprayed from the second sprayers 63 to the substrate flows from the liquid outlet of the pickling tank 62 into the second liquid collection tank 64, and then enters the second filtering mechanism 61 from the second liquid collection tank 64. The second filtering mechanism 61 filters out impurities in the solution and supplies the filtered solution to the second sprayers 63. As a result, circulation is realized and the production cost is saved. When the pickling of a certain number of substrates is completed and a concentration of the pickling solution output from the second filtering mechanism 61 is lower than a predetermined value, the second supply device 90 may supply extra pickling solution to replenish the first liquid inlet of the second liquid collection tank 64.

As shown in FIGS. 1A and 1B, the electrochemical deposition apparatus set further includes: a first cleaning device 71 located on a side of the antioxidation treatment device 20 close to the electrochemical deposition device 10 and configured to spray a first cleaning liquid toward the substrate formed with the electrochemical deposition film layer. For example, the first cleaning liquid is water.

The process of the transmission device 30 driving the substrate to move from the electrochemical deposition device 10 to the antioxidation treatment device 20 specifically includes: the transmission device 30 drives the substrate to move from the electrochemical deposition device 10 to the first cleaning device 71, and from the first cleaning device 71 to the antioxidation treatment device 20 in sequence. Therefore, before reaching the region where the antioxidation process is to be performed for antioxidation treatment, the electrochemically deposited substrate has been cleaned with the first cleaning device 71. Thus, the substrate is cleaned before the electrochemical deposition film layer on the substrate is subjected to antioxidation treatment, thereby preventing impurities on the electrochemical deposition film layer from affecting uniformity of the protective layer formed in the antioxidation treatment process.

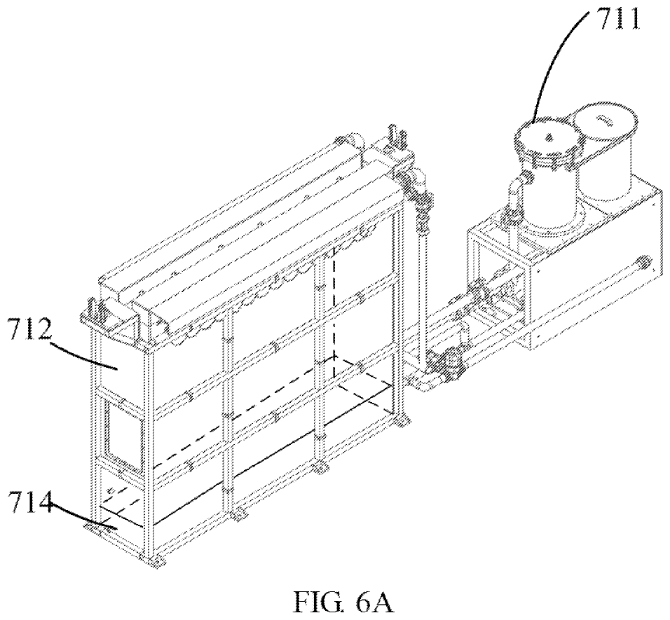

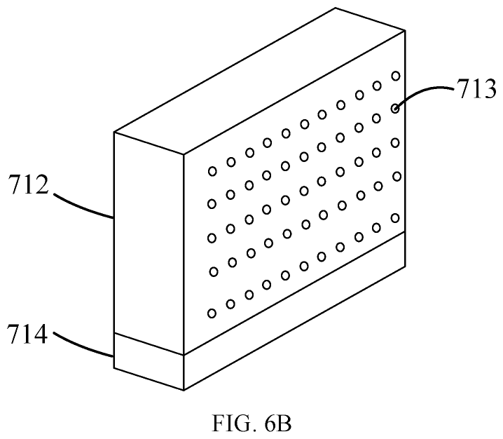

FIG. 6A is a schematic diagram of a first cleaning device provided in some embodiments of the present disclosure. FIG. 6B is a schematic diagram showing a positional relationship among a cleaning tank, a third liquid collection tank, and third sprayers within a first cleaning device provided in some embodiments of the present disclosure. As shown in FIGS. 6A and 6B, the first cleaning device 71 includes a third filtering mechanism 711, a cleaning tank 712, and a third liquid collection tank 714, and includes a plurality of third sprayers 713 disposed in the cleaning tank 712.

The third liquid collection tank 714 is located below the cleaning tank 712. The third liquid collection tank 714 has: a first liquid inlet in communication with a cleaning source to receive a cleaning liquid supplied from the cleaning source; and a second liquid inlet in communication with a liquid outlet of the cleaning tank 712. A liquid outlet of the third liquid collection tank 714 is in communication with a liquid inlet of the third filtering mechanism 711, a liquid outlet of the third filtering mechanism 711 is in communication with liquid inlets of the third sprayers 713, and liquid outlets of the third sprayers 713 face a region of the first cleaning device where the cleaning process is to be performed, so as to spray the first cleaning liquid toward the substrate. For example, the third sprayers 713 are arranged in an array in the cleaning tank 712.

In the first cleaning device, after cleaning the substrate, the cleaning liquid sprayed from the third sprayers 713 flows from the liquid outlet of the cleaning tank 712 into the third liquid collection tank 714, and then enters the third filtering mechanism 711 through the third liquid collection tank 714, where the third filtering mechanism 711 filters out impurities in the cleaning liquid and supplies the filtered cleaning liquid to the third sprayers 713. As a result, circulation is realized and the production cost is saved. When the cleaning of a certain number of substrates is completed, the cleaning liquid in the third cleaning tank 712 is drained, and a new cleaning liquid is introduced into the third liquid collection tank 714.

In some embodiments, as shown in FIGS. 1A and 1B, the electrochemical deposition apparatus set further includes: a second cleaning device 72 and a drying device (not shown). The second cleaning device 72 is located on a side of the first cleaning device 71 away from the antioxidation treatment device 20 and is configured to spray a second cleaning liquid toward the substrate. The drying device is configured to dry the substrate.

The transmission device 30 is further configured to drive the substrate to move from the antioxidation treatment device 20 to the second cleaning device 72 and the drying device in sequence so that the substrate is subjected to a second cleaning and drying after the antioxidation treatment.

The second cleaning device may have the same structure as the first cleaning device, which is not repeated here; and the second cleaning liquid may be the same as the first cleaning liquid and both are water. For example, the drying device may include an air knife disposed above the cleaning tank 712 of the second cleaning device.

As shown in FIGS. 1A and 1B, the electrochemical deposition apparatus set further includes a storage rack 80. The storage rack 80 is located on a side of the electrochemical deposition device 10 away from the antioxidation treatment device 20, for example, between the electrochemical deposition device 10 and the loading device 40. The storage rack 80 is configured to store the carrier 31. For example, in the process, when a first carrier 31 and the substrate carried thereon are located in the receiving tank 11 of the electrochemical deposition device 10 and a second carrier 31 and the substrate carried thereon are located in the pickling tank 62, if the loading device 40 receives a third substrate and loads the third substrate onto a third carrier 31, the third carrier 31 may be placed on the storage rack 80 through movement of the bracket 32 and grasping action of the grasping mechanism 34.

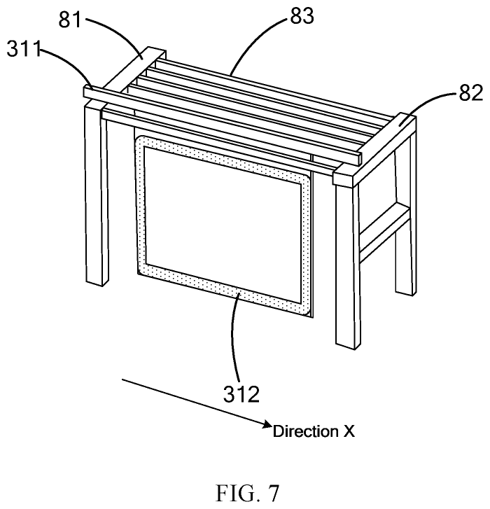

FIG. 7 is a schematic diagram of a storage rack provided in some embodiments of the present disclosure. As shown in FIG. 7, the storage rack 80 includes: a first support part 81, a second support part 82, and a plurality of connection parts 83 between the first support part 81 and the second support part 82. Each two adjacent connection parts 83 has a gap therebetween which serves as a storage station for storing the carrier 31. The carrier 31 includes: a bridge part 311 and a bearing part 312 connected to the bridge part 311. The bearing part 312 is configured to bear the substrate. The structure of the bearing part 312 is not particularly limited in the embodiments of the present disclosure as long as the substrate can be stably born. A distance between the first support part 81 and the second support part 82 is greater than a width of the bearing part 312 and less than a width of the bridge part 311 so that the bearing part 312 can pass through the gap between the two adjacent connection parts 83; and two ends of the bridge part 311 can be placed on the first support part 81 and the second support part 82.

It should be noted that the width of the bearing part 82 (or the bridge part 81) refers to a distance of the bearing part 82 (or the bridge part 81) in the direction X in FIG. 7.

FIG. 8 is a schematic diagram of a second supply device provided in some embodiments of the present disclosure. As shown in FIG. 8, the second supply device 92 includes an operation box 920, and includes a first liquid tank and a second liquid tank arranged in the operation box 920. The operation box 920 is provided with a first inlet 921a, a second inlet 922a, a first outlet 921b, and a second outlet 922b. The first inlet 921a is in communication with a liquid inlet of the first liquid tank, while the first outlet 921b is in communication with a liquid outlet of the first liquid tank. The second inlet 922a is in communication with a liquid inlet of the second liquid tank, while the second outlet 922b is in communication with a liquid outlet of the second liquid tank.

Next, the process of performing electrochemical deposition by the electrochemical deposition apparatus set will be described. The feeding device 50 receives the substrate to be electrochemically deposited, turns the substrate from a horizontal state to an upright state, and delivers the substrate to the loading device 40.

The loading device 40 loads the substrate to be electrochemically deposited onto the carrier 31.

The lifting beam 323 of the bracket 32 moves downward, and then upward after the carrier 31 is grasped by the grasping mechanism 34. Thereafter, the bracket 32 moves along the guide rails 33 to the above of the pickling device 60. Then, the lifting beam 323 moves downward so that the substrate carried on the carrier 31 enters the pickling tank 62 of the pickling device 60, and the second sprayers in the pickling tank 62 sprays the pickling solution toward the substrate in the pickling tank 62 to pickle the substrate.

After the substrate is pickled, the lifting beam 323 moves upward to drive the carrier 31 and the substrate carried thereon to move upward. Thereafter, the bracket 32 moves along the guide rails 33 to the above of the electrochemical deposition device 10. Then the lifting beam 323 moves downward so that the substrate carried on the carrier 31 enters the receiving tank 11 of the electrochemical deposition device 10, where an electrolyte solution for electrochemical deposition is received. An electric field is formed between the anode structure in the receiving tank 11 and the carrier 31. As a result, metal ions in the electrolyte solution are attached to the substrate to form an electrochemical deposition film layer.

After the electrochemical deposition film layer is formed on the substrate, the lifting beam 323 moves upward to drive the carrier 31 and the substrate carried thereon to move upward. Thereafter, the bracket 32 moves along the guide rails 33 to the above of the first cleaning device 71. Then the lifting beam 323 moves downward so that the substrate carried on the carrier 31 enters the cleaning tank 712 of the first cleaning device 71, and the sprayers in the cleaning tank 712 spray a cleaning agent (e.g., water) toward the substrate to clean the substrate for the first time.

After the first cleaning of the substrate, the lifting beam 323 moves upward to drive the carrier 31 and the substrate carried thereon to move upward. Thereafter, the bracket 32 moves along the guide rails 33 to the above of the antioxidation treatment device 20. Then the lifting beam 323 moves downward so that the substrate carried on the carrier 31 enters the antioxidation tank 22 of the antioxidation treatment device 20, and the first sprayers 23 in the antioxidation tank 22 spray an antioxidant solution toward the substrate to form a protective layer on a surface of the electrochemical deposition film layer on the substrate.

After the protective layer is formed on the substrate, the lifting beam 323 moves upward to drive the carrier 31 and the substrate carried thereon to move upward. Thereafter, the bracket 32 moves along the guide rails 33 to the above of the second cleaning device 72. Then the lifting beam 323 moves downward so that the substrate carried on the carrier 31 enters the cleaning tank of the second cleaning device 72, and the sprayers in the cleaning tank spray a cleaning agent (e.g., water) toward the substrate to clean the substrate for a second time.

After the second cleaning of the substrate, the lifting beam 323 moves upward to remove the substrate from the cleaning tank of the second cleaning device 72 and to the drying device, where the drying device dries the substrate.

Thereafter, the bracket 32 moves along the guide rails 33 to the above of the loading device 40. The lifting beam 323 moves downward, and the loading device 40 takes the substrate on the carrier and transfers the substrate to the feeding device 50, which then transfers the substrate to a process device for a next process.

It should be noted that, although the above process is described for the same substrate, in the embodiments of the present disclosure, the number of the electrochemical deposition device 10 may be multiple (more than one). In this case, when the electrochemical deposition film layer is formed on the substrate, the substrate on the carrier 31 is driven to enter the receiving tank 11 of one of the electrochemical deposition devices 10 through movements of the bracket, without entering the receiving tank 11 of each of the electrochemical deposition devices 10.

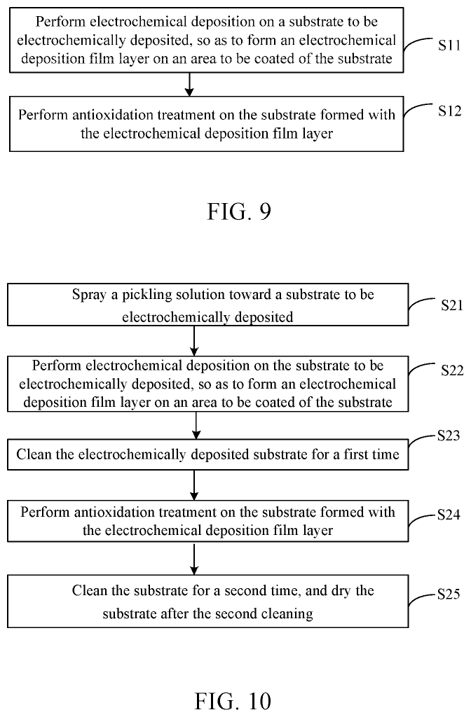

FIG. 9 is a flowchart of an electrochemical deposition method provided in some embodiments of the present disclosure. As shown in FIG. 9, the electrochemical deposition method includes the following steps S11 to S12.

At step S11, performing electrochemical deposition on a substrate to be electrochemically deposited, so as to form an electrochemical deposition film layer on an area to be coated of the substrate.

At step S12, performing antioxidation treatment on the substrate formed with the electrochemical deposition film layer.

In an embodiment of the present disclosure, after the electrochemical deposition film layer is formed on the substrate, the electrochemical deposition film layer on the substrate is further subjected to antioxidation treatment to form a protective layer on a surface of the electrochemical deposition film layer, thereby preventing the electrochemical deposition film layer from being oxidized, and ensuring the electrical performance of the electrochemical deposition film layer.

FIG. 10 is a flowchart of an electrochemical deposition method according to a further embodiment of the present disclosure. As shown in FIG. 10, the electrochemical deposition method includes the following steps S21 to S25.

At step S21, spraying a pickling solution toward a substrate to be electrochemically deposited.

At step S22, performing electrochemical deposition on a substrate to be electrochemically deposited, so as to form an electrochemical deposition film layer on an area to be coated of the substrate.

At step S23, cleaning the electrochemically deposited substrate for a first time. For example, the substrate is washed with water.

At step S24, performing antioxidation treatment on the substrate formed with the electrochemical deposition film layer. For example, an antioxidant solution is sprayed toward the electrochemical deposition film layer so that the antioxidant solution chemically reacts with the electrochemical deposition film layer to form a protective layer on a surface of the electrochemical deposition film layer.

At S25, cleaning the substrate for a second time, and drying the substrate after the second cleaning. The second cleaning of the substrate may specifically include washing the substrate with water.

In some embodiments, the above steps S11 to S12, and S21 to S25, are implemented when the substrate is in an upright state.

In some embodiments, before the above steps S11 and S21, the electrochemical deposition method may further include: receiving the substrate in a horizontal state, and turning the substrate from the horizontal state into an upright state. After the above steps S12 and S25, the electrochemical deposition method may further include: turning the substrate from the upright state back to the horizontal state. After turning to the upright (vertical) state, the substrate is subjected to a series of treatments such as electrochemical deposition, antioxidation, pickling, water washing and the like, which has high the treatment efficiency and reduces impurities on the surface of the substrate.

The electrochemical deposition method in the embodiments of the present disclosure may be implemented with the electrochemical deposition apparatus set in the foregoing embodiments; the specific process is as described above and will not be repeated here.

It will be appreciated that the above implementations and embodiments are merely exemplary implementations for the purpose of illustrating the principle of the present disclosure, and the present disclosure is not limited thereto. Various modifications and improvements can be made by a person having ordinary skill in the art without departing from the spirit and essence of the present disclosure. Accordingly, all of the modifications and improvements also fall into the protection scope of the present disclosure.

What is claimed is:

1. An electrochemical deposition apparatus set, comprising:
an electrochemical deposition device configured to form an electrochemical deposition film layer on an area to be coated of a substrate;
an antioxidation treatment device located on a side of the electrochemical deposition device and configured to perform antioxidation treatment on the substrate formed with the electrochemical deposition film layer; and
a transmission device configured to carry the substrate and drive the substrate to move at least from the electrochemical deposition device to the antioxidation treatment device.

2. The electrochemical deposition apparatus set according to claim 1, wherein the antioxidation treatment device comprises:
an antioxidation tank;
a first liquid collection tank having a first liquid inlet in communication with a supply device supplying an antioxidant solution, and a second liquid inlet in communication with a liquid outlet of the antioxidation tank;
a first filtering mechanism having a liquid inlet in communication with the liquid outlet of the first liquid collection tank, wherein the first filtering mechanism is configured to filter the received antioxidant solution; and
a plurality of first sprayers arranged in the antioxidation tank, the first sprayers being in communication with the liquid outlet of the first filtering mechanism, and configured to spray the filtered antioxidant solution toward the substrate formed with the electrochemical deposition film layer;
wherein the antioxidant solution chemically reacts with the electrochemical deposition film layer to form a protective layer on a surface of the electrochemical deposition film layer.

3. The electrochemical deposition apparatus set according to claim 1, further comprising a pickling device configured to spray a pickling solution toward the area to be coated of the substrate; and
wherein the transmission device is further configured to drive the substrate to move from the pickling device to the electrochemical deposition device.

4. The electrochemical deposition apparatus set according to claim 3, wherein the pickling device comprises:
a pickling tank;
a second liquid collection tank having a first liquid inlet in communication with a supply device supplying a pickling solution, and a second liquid inlet in communication with a liquid outlet of the pickling device;
a second filtering mechanism having a liquid inlet in communication with the liquid outlet of the second liquid collection tank, and configured to filter the received pickling solution; and
a plurality of second sprayers arranged in the pickling tank, the second sprayers being in communication with the liquid outlet of the second filtering mechanism, and configured to spray the filtered pickling solution toward the substrate.

5. The electrochemical deposition apparatus set according to claim 1, further comprising: a first cleaning device located on a side of the antioxidation treatment device close to the electrochemical deposition device and configured to spray a first cleaning liquid toward the substrate formed with the electrochemical deposition film layer; and
wherein the transmission device is configured to drive the substrate to move from the electrochemical deposition device to the first cleaning device, and from the first cleaning device to the antioxidation treatment device.

6. The electrochemical deposition apparatus set according to claim 5, further comprising: a second cleaning device and a drying device;
wherein the second cleaning device is located on a side of the antioxidation treatment device away from the first cleaning device, and is configured to spray a second cleaning liquid toward the substrate that has been subjected to the antioxidation treatment;
wherein the drying device is configured to dry the substrate that has been cleaned by the second cleaning liquid; and
wherein the transmission device is further configured to drive the substrate to move from the antioxidation treatment device to the second cleaning device and the drying device in sequence.

7. The electrochemical deposition apparatus set according to claim 1,
wherein the electrochemical deposition device and the antioxidation treatment device are arranged along a first direction;
wherein the transmission device comprises: guide rails, a bracket, a grasping mechanism, and a driving mechanism; and
wherein the guide rails are arranged on opposite sides of the electrochemical deposition device and extend along the first direction; the bracket is slidably arranged on the guide rails; the grasping mechanism is arranged on the bracket and configured to pick and place the substrate; and the driving mechanism is connected to the bracket and configured to drive the bracket to move along the guide rails so as to drive the substrate to move at least from the electrochemical deposition device to the antioxidation treatment device.

8. The electrochemical deposition apparatus set according to claim 7,
wherein the transmission device further comprises a carrier configured to carry the substrate; and
wherein the grasping mechanism is configured to pick and place the carrier to realize the pick and place of the substrate.

9. The electrochemical deposition apparatus set according to claim 7,
wherein the bracket comprises: a first upright portion, a second upright portion, and a lifting beam connected between the first upright portion and the second upright portion;
wherein the first upright portion and the second upright portion are respectively arranged on the guide rails on opposite sides of the electrochemical deposition device, and the grasping mechanism is arranged on the lifting beam.

10. The electrochemical deposition apparatus set according to claim 8, further comprising: a feeding device and a loading device;
wherein the feeding device is configured to receive the substrate to be electrochemically deposited, turn the received substrate from a horizontal state to an upright state, and deliver the substrate to the loading device; and
wherein the loading device is located between the feeding device and the electrochemical deposition device, and configured to fix the substrate in the upright state onto the carrier.

11. The electrochemical deposition apparatus set according to claim 8, further comprising: a storage rack located on a side of the electrochemical deposition device away from the antioxidation treatment device, and configured to store the carrier.

12. An electrochemical deposition method, comprising:
performing electrochemical deposition on a substrate to be electrochemically deposited, so as to form an electrochemical deposition film layer on an area to be coated of the substrate; and
performing antioxidation treatment on the substrate formed with the electrochemical deposition film layer.

13. The electrochemical deposition method according to claim 12,
wherein the step of performing electrochemical deposition on the substrate to be electrochemically deposited, and the step of performing antioxidation treatment on the substrate formed with the electrochemical deposition film layer are implemented when the substrate is in an upright state.

14. An electrochemical deposition method, the method comprising:
spraying a pickling solution toward a substrate to be electrochemically deposited;
performing electrochemical deposition on the substrate sprayed with the pickling solution, so as to form an electrochemical deposition film layer on an area to be coated of the substrate;
cleaning the substrate formed with the electrochemical deposition film layer for a first time;
performing antioxidation treatment on the substrate after the first cleaning; and
cleaning the substrate subjected to the antioxidation treatment for a second time, and drying the substrate after the second cleaning.

15. The electrochemical deposition method according to claim 14,
wherein before spraying the pickling solution toward the substrate to be electrochemically deposited, the method further comprises: receiving the substrate in a horizontal state, and turning the substrate into an upright state; and
wherein after drying the substrate after the second cleaning, the method further comprises: turning the substrate from the upright state back to the horizontal state.
